(19) United States
(12) Patent Application Publication
(10) Pub. No.: US 2011/0141698 A1
(43) Pub. Date: Jun. 16, 2011

(54) HEAT SPREADING STRUCTURE

(75) Inventors: Kuo-Chan Chiou, Tainan City (TW); Ching-Ting Huang, Kaohsiung City (TW); Chen-Lung Lin, Taichung County (TW)

(73) Assignee: INDUSTRIAL TECHNOLOGY RESEARCH INSTITUTE, HSINCHU (TW)

(21) Appl. No.: 12/730,082

(22) Filed: Mar. 23, 2010

(30) Foreign Application Priority Data
Dec. 15, 2009 (TW) TW98142843

(51) Int. Cl. H05K 7/20

(52) U.S. Cl. 361/708

(57) ABSTRACT

The disclosed is a thermal interface layer disposed between a heat-generating apparatus and a thermal dissipation component. The thermal interface layer is composed of a mixture of a resin matrix and highly thermal conductive powders, wherein the resin matrix is obtained by reacting epoxy resin, diisocyanate, and amino curing agent. Tuning the ratio of the diisocyanate and the epoxy resin may modify the hardness and the viscosity of the thermal interface material. After repeated tested at high temperature for long period, the described thermal interface layer still remained viscose, soft, and thermally resistant. The filling effect of the thermal interface material in the voids between the electronic device and the sink is largely improved. The thermoplastic thermal interface material may fill the void or cavity on the surface of the electronic apparatus, thereby improving the heat spreading efficiency of the whole structure.

### CROSS REFERENCE TO RELATED APPLICATIONS

This Application claims priority of Taiwan Patent Application No. 098142843, filed on Dec. 15, 2009, the entirety of which is incorporated by reference herein.

### BACKGROUND OF THE INVENTION

1. Field of the Invention

The present invention relates to a thermal interface material, and in particular relates to the heat spreading structure utilizing the same.

2. Description of the Related Art

Not only are size properties such as light, thin, small, and short demanded for the improvement of electronic devices, the operational temperature of the device's components (such as central process unit (CPU)) must be low enough for the device to function efficiently. If waste heat from the device cannot be efficiently removed, temperature will increase to the point where functionality is degraded and permanent damage may result. Accordingly, requirements for heat dissipation in electronic devices will increase as time goes by.

Waste heat is generally thermally conducted from electronic components to heat dissipation devices such as heat sinks where the excess heat is then dissipated by convection or radiation. Surfaces of the electronic component and the heat sink are typically not completely smooth; therefore, it is difficult to achieve full contact between the surfaces. Because the air in the voids has poor thermal conductivity, the voids between the electronic device and the heat sink will dramatically reduce thermal conductivity. As such, a thermal interface material is used between the electronic device and the heat sink to fill the voids to enhance thermal conductivity.

The major component of contemporary thermal interface material is siloxane resin. The ceramic powders such as aluminum oxide are added to the resin to improve thermal conductivity and then processed to form sheets, pads, belts or films. In order to enhance the filling effect of the thermal interface material in the voids between the electronic device and the sink, the thermoplastic rubber or wax is further added such that the thermal interface material undergoes a phase change property. The thermal interface material including the thermoplastic rubber requires higher pressure to fill the voids in practice. The material including the wax is softer and easier to process. However, the rubber and the wax belong to an organic resin which has low molecular weight. Hence, rubber and wax are easily degraded and dissipated at high temperatures due to their low thermal endurance. Therefore, thermal interface material including thermoplastic rubber and wax has poor thermal stability, and its filling effect in the voids between the electronic device and the sink is reduced. The contact area between the electronic device and the thermal dissipation device will be lowered when utilizing thermal interface material having low filling effect in the voids between the electronic device and the sink. The whole structure has lower heat spreading capacity and also has a shorter lifetime.

Accordingly, a thermal interface material different from the general composition is called for and it should enhance the contact area between the electronic component and the heat dissipation device even during periods of prolonged operation. As such, the heat spreading effect of the whole structure will be improved.

### BRIEF SUMMARY OF THE INVENTION

The invention provides a heat spreading structure, comprising a heat-generating apparatus; a thermal dissipation component; and a thermal interface layer disposed between the heat-generating apparatus and the thermal dissipation component, wherein the thermal interface layer comprises 100 parts by weight of resin matrix; and 25 to 1900 parts by weight of high thermal conductive powder; wherein the matrix resin is obtained by reacting an epoxy resin, a diisocyanate, and an amino curing agent; wherein the amino group of the amino curing agent and the isocyanate group of the diisocyanate have a molar ratio of 1:0.51 to 1:0.99; wherein the amino group of the amino curing agent and the epoxy group of the epoxy resin have a molar ratio of 1:0.49 to 1:0.01.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view showing the heat spreading structure of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

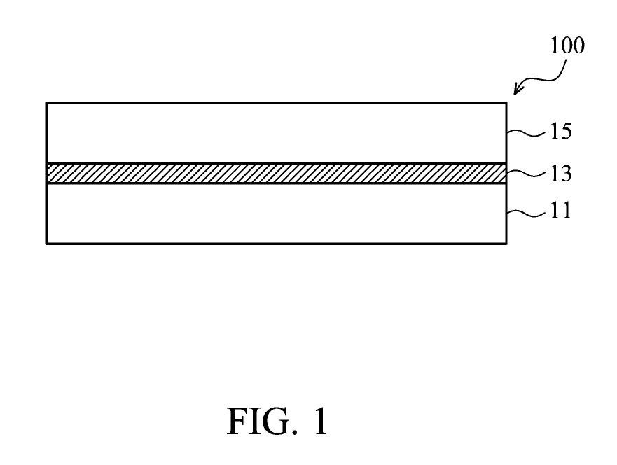

FIG. 1 shows a heat spreading structure 100, including a heat-generating apparatus 11, a thermal dissipation component 15, and a thermal interface layer 13 disposed therebetween. The heat-generating devices include general electronic products applied in various fields such as 3C products, industry, mobile, medical, aeronautic, astronautic, and communication, e.g. main board, CPU, or display, or other heat-generating devices such as LED lamp, heat engine, refrigerator, or carrier engine. The described heat-generating device performance is easily degraded, even to breaking down due to heat accumulation during operation, a thermal dissipation component 15 such as heat sink, heat pipe, or fan is needed to dissipate heat. The thermal interface layer 13 is applied to closely adhere the heat-generating device 11 and the thermal dissipation component 15, such that no void is formed therebetween and no reduction in thermal conductivity occurs.

The thermal interface layer 13 includes 100 parts by weight of matrix resin and 25 to 1900 parts by weight of high thermal conductive powder. The high conductive powder is applied to enhance the thermal conductivity of the thermal interface layer. If the high thermal conductive powder amount is too low then it cannot enhance the thermal conductivity of the thermal interface layer. If the high thermal conductive powder is too high then the mechanical properties of the matrix resin will be degraded. The high thermal conductive powder includes metal particle, metal oxide particle, ceramic particle, carbon material, low melting point alloy, or combinations thereof. In one embodiment, the high thermal conductive powder includes copper, gold, nickel, silver, aluminum, boron nitride, aluminum oxide, aluminum nitride, magnesium nitride, zinc oxide, silicon carbide, beryllium oxide, diamond, graphite, tungsten carbide, carbon fiber, carbon nanotube, or mixtures thereof. For example, the high thermal conductive powder has at least two diameter distributions and/or at least two compositions to improve the filling factor of the high thermal conductive powder in the matrix resin, thereby further enhancing the thermal conductivity of the thermal interface layer.

The matrix resin is obtained by reacting an epoxy resin, a diisocyanate, and an amino curing agent. The amino group of the amino curing agent and the isocyanate group of the diisocyanate have a molar ratio of 1:0.51 to 1:0.99, and the amino group of the amino curing agent and the epoxy group of the epoxy resin have a molar ratio of 1:0.49 to 1:0.01. If the diisocyanate ratio is too low, the matrix resin will not have a soft and thermoplastic property. On the other hand, if the diisocyanate content is too high even without the epoxy resin, the matrix resin will have poor thermal endurance.

The amino curing agents include rubber, polyether, or polyester having a terminal amino group. In one embodiment, the amino curing agent is D230, D400, or D2000 commercially available from Huntsman, or combinations thereof. In one embodiment, the amino curing agent has a weight-average molecular weight (in abbreviate Mw) of 200 to 5000, preferably of 500 to 4000, and more preferably of 1500 to 3000. If the Mw of the amino curing agent is too high, the thermal interface layer will lose softness and be too tough to efficiently fill the void. If the Mw of the amino curing agent is too low, the mechanical strength of the thermal interface layer will be degraded, such that the thermal interface layer won't be able to maintain a constant shape.

The diisocyanate can be methylene diphenyl diisocyanate (in abbreviate MDI), toluene diisocyanate (in abbreviate TDI), hexamethylene diisocyanate (in abbreviate HDI), isophorone diisocyanate (in abbreviate IPDI), norbornene diisocyanate (in abbreviate NBDI), or combinations thereof. The amino curing agent and the mono-isocyanate will react to form an end-capped product which cannot grow anymore. The multi-isocyanate and the amino curing agent and/or the epoxy resin will multi-react to form a network of polymers which has a high degree of crosslinking which leads to thermal softening. Note that the resin matrix is obtained by reacting the diisocyanate rather than the multi-isocyanate or the mono-isocyanate, such that the resin matrix of the invention has a proper crosslink degree, a constant shape, and an obvious thermal softening temperature.

The described epoxy resin has m epoxy groups in backbone or terminal, and the backbone is aromatic. In one embodiment, the m is 2. As known from experiments of the invention, the thermal interface material obtained by reacting the epoxy resin including aromatic backbone has better thermal endurance than the thermal interface material obtained by reacting the epoxy resin including aliphatic backbone. In one embodiment, the epoxy resin is EPON828, commercially available from Shell, H-4032D or EXA-830LVP commercially available from DIC, 202 commercially available from Chang Chun Chemical, or other epoxy resin having aromatic backbone.

In another embodiment, the thermal interface layer 13 further includes less than 50 parts by weight of an additive on the basis of 100 parts by weight of the matrix resin. The additive comprises a catalyst, a de-foaming agent, an inhibitor, an anti-oxidant, a flame retardant, a leveling agent, a releasing agent or combinations thereof. The additive functions to benefit the physical and/or chemical properties of the thermal interface layer 13. If the additive amount is too high, the shaping or self-adhering properties of the thermal interface layer will be influenced, the process difficulty thereof will be increased, and the thermal conductivity thereof will be reduced. In addition, most of the additive is small molecular, such that the additive may dissipate after long period of use.

Because conventional thermal phase change material including rubber and wax has insufficient thermal endurance, it cannot be used at a temperatures of 120° C. for long periods. The thermal interface layer 13 is a thermoplastic material and has a high thermal stability/endurance (>150° C.)., it therefore has a long lifetime due to its ability to maintain suppleness and not become fatigued after extended periods of use at high temperatures. Additionally, when the heat generating device 11 is operated at normal temperature, the thermal interface material, having low viscosity and high softness, may efficiently fill the voids, cavities, or concaves between the heat-generating device 11 and the thermal dissipation component 15, such that the heat spreading ability of the whole device is improved.

### EXAMPLES

The thermal conductivity of the following examples was measured by the “Hot disk standard method” ISO22007.

The hardness (Shore A) of the following examples was measured by ASTM D2240 standard.

The viscosity of the following examples was measured by AR2000ADVANCED RHEOMETER.

### Example 1

2 g of epoxy resin EPON828 (0.005 mole, commercially available from Shell), 1.5 g of MDI (0.006 mole), and 22 g of amino curing agent D2000 (0.011 mole, commercially available from Huntsman) were charged in a reactor (250 mL) and stirred at high speed to become even, 76.5 g of aluminum oxide powder and 20 g of toluene was slowly added. The mixture was stirred at high speed for 5 minutes, dispersed by a roller 3 times, and then transferred to an oven to be baked at 150° C. for 15 minutes to dry the solvent, such that a thermal interface material having high thermal endurance and a solid content of 75 wt % was obtained. The thermal conductivity, hardness, and viscosity of the thermal interface material is tabulated in Table 1. As shown in Table 1, the excellent thermal endurance thereof was determined by the material softness without obvious change after baking the thermal interface material at 150° C. for 2 days. In addition, because the thermal interface material had a viscosity of about 55,000 Pa-s at room temperature, and a viscosity of 1,500 Pa-s at 75° C., it indicated that the thermal interface material was thermoplastic.

EPON828 was presented as Formula 1, wherein n was about 1 to 2. MDI was presented as Formula 2. D2000 was presented as Formula 3, wherein x was about 33.

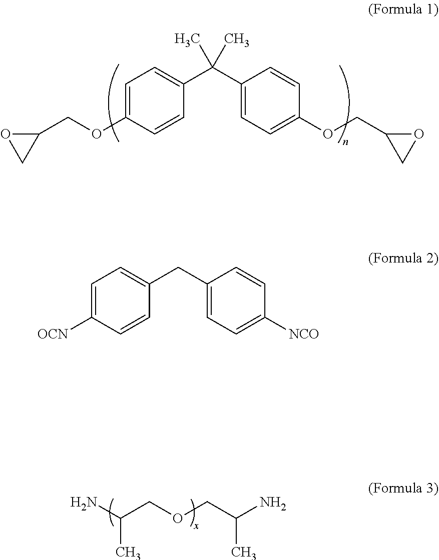

### Comparative Example 1

2.5 g of MDI (0.01 mole) and 20 g of D2000 (0.01 mole) were charged in a reactor (250 mL) and stirred at high speed to be even, and 67.5 g of aluminum oxide powder and 20 g of toluene was slowly added. The mixture was stirred at high speed for 5 minutes, dispersed by a roller 3 times, and then transferred to an oven to be baked at 150° C. for 15 minutes to dry the solvent such that a thermal interface material having a solid content of 75 wt % was obtained. The thermal conductivity, hardness, and viscosity of the thermal interface material is tabulated in Table 1. As shown in comparison with Table 1, the matrix resin, obtained from the reactions without the epoxy resin, would be thermally degraded and could not operate at high temperature for long periods, such that its viscosity was too low to be measured.

### Comparative Example 2

1.6 g of aliphatic epoxy resin 732 (0.005 mole, commercially available from Dow Chemical), 1.5 g of MDI (0.006 mole), and 22 g of amino curing agent D2000 (0.011 mole) were charged in a reactor (250 mL) and stirred at high speed to become even, 75.3 g of aluminum oxide powder and 20 g of toluene was slowly added. The mixture was stirred at high speed for 5 minutes, dispersed by a roller 3 times, and then transferred to an oven to be baked at 150° C. for 15 minutes to dry the solvent such that a thermal interface material having a solid content of 75 wt % was obtained. The thermal conductivity, hardness, and viscosity of the thermal interface material were tabulated in Table 1. As shown in comparison with Table 1, the matrix resin, obtained by reacting the epoxy resin having an aliphatic backbone other than the aromatic backbone, would be thermally degraded and could not be operated at high temperature for long periods, such that its viscosity was too low to be measured.

The epoxy resin 732 was presented as Formula 4, wherein n was about 9.

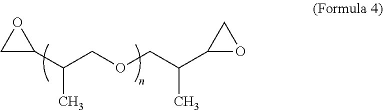

### Comparative Example 3

4.2 g of epoxy resin EPON828 (0.011 mole) and 22 g of amino curing agent D2000 (0.011 mole) were charged in a reactor (250 mL) and stirred at high speed to become even, 78.6 g of aluminum oxide powder and 20 g of toluene was slowly added. The mixture was stirred at high speed for 5 minutes, dispersed by a roller 3 times, and then transferred to an oven to be baked at 150° C. for 15 minutes to dry the solvent, such that a thermal interface material having high thermal endurance and a solid content of 75 wt % was obtained. The thermal conductivity, hardness, and viscosity of the thermal interface material were tabulated in Table 1. As shown in comparison with Table 1, the matrix resin, obtained from the reactions without the diisocyanate would have high thermal endurance. However, the softness of the thermal interface material was insufficient, such that the filling effect of the thermal interface material was too poor to fill the cavity, void, or defect on the surface of the heat-generating apparatus. Moreover, the viscosities of the thermal interface layer at room temperature and 75° C. were similar, this meant that the thermal interface material was not thermoplastic.

TABLE 1

| | | Example 1 | Comparative 1 | Comparative 2 | Comparative 3 |
|---|---|---|---|---|---|
| Epoxy resin | | EPON828 | none | 732 | EPON828 |
| Diisocyanate | | MDI | MDI | MDI | none |
| Amino curing agent | | D2000 | D2000 | D2000 | D2000 |
| High thermal conductive | | Al₂O₃ | Al₂O₃ | Al₂O₃ | Al₂O₃ |
| powder | | | | | |
| Thermal conductivity | | 0.85 | 0.87 | 0.88 | 0.88 |
| (W/mK) | | | | | |
| Hardness | 150° C., 0 day | 17 | 11 | 5 | 86 |
| (Shore A) | 150° C., 1 day | 18 | 0 (thermal | 0 (thermal | 86 |
| | | | degraded) | degraded) | |
| | 150° C., 2 days | 22 | 0 (thermal | 0 (thermal | 87 |
| | | | degraded) | degraded) | |
| Viscosity | 25° C. | 55,000 | Not available | Not available | 100,000 |
| (Pa-s) | 75° C. | 1,500 | Not available | Not available | 80,000 |

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat spreading structure, comprising:
a heat-generating apparatus;
a thermal dissipation component; and
a thermal interface layer disposed between the heat-generating apparatus and the thermal dissipation component,
wherein the thermal interface layer comprises:
100 parts by weight of resin matrix; and
25 to 1900 parts by weight of high thermal conductive powder;
wherein the matrix resin is obtained by reacting an epoxy resin, a diisocyanate, and an amino curing agent;
wherein the amino group of the amino curing agent and the isocyanate group of the diisocyanate have a molar ratio of 1:0.51 to 1:0.99;
wherein the amino group of the amino curing agent and the epoxy group of the epoxy resin have a molar ratio of 1:0.49 to 1:0.01.

2. The heat spreading structure as claimed in claim 1, wherein the heat-generating apparatus comprises chip, central process unit, main board, display, LED lamp, heat engine, refrigerator, or carrier engine.

3. The heat spreading structure as claimed in claim 1, wherein the thermal dissipation component comprises fan, heat pipe, heat sink, or combinations thereof.

4. The heat spreading structure as claimed in claim 1, wherein the high thermal conductive powder comprises metal particle, metal oxide particle, ceramic particle, carbon material, low melting point alloy, or combinations thereof.

5. The heat spreading structure as claimed in claim 1, wherein the high thermal conductive powder comprises copper, gold, nickel, silver, aluminum, boron nitride, aluminum oxide, aluminum nitride, magnesium nitride, zinc oxide, silicon carbide, beryllium oxide, diamond, graphite, tungsten carbide, carbon fiber, carbon nanotube, or mixtures thereof.

6. The heat spreading structure as claimed in claim 1, wherein the high thermal conductive powder has at least two diameter distributions and/or at least two compositions.

7. The heat spreading structure as claimed in claim 1, wherein the amino curing agent comprises rubber, polyether, or polyester having a terminal amino group, and has a weight-average molecular weight of 200 to 5000.

8. The heat spreading structure as claimed in claim 1, wherein the diisocyanate comprises methylene diphenyl diisocyanate, toluene diisocyanate, hexamethylene diisocyanate, isophorone diisocyanate, norbornene diisocyanate, or combinations thereof.

9. The heat spreading structure as claimed in claim 1, wherein the epoxy resin has an aromatic backbone.

10. The heat spreading structure as claimed in claim 1, wherein the thermal interface layer further comprises less than 50 parts by weight of additive, and the additive comprises a catalyst, a de-foaming agent, an inhibitor, an anti-oxidant, a flame retardant, a leveling agent, a releasing agent, or combinations thereof.
